(19) United States
(12) Patent Application Publication
(10) Pub. No.: US 2009/0309209 A1
(43) Pub. Date: Dec. 17, 2009

(54) Die Rearrangement Package Structure and the Forming Method Thereof

(76) Inventor: Yu-Ren CHEN, Hsinchu city (TW)

Correspondence Address: SINORICA, LLC, 2275 Research Blvd., Suite 500, ROCKVILLE, MD, 20850, US

(21) Appl. No.: 12/353,275

(22) Filed: Jan. 14, 2009

(30) Foreign Application Priority Data
Jun. 12, 2008 (TW) 097121903

(51) Int. Cl. H01L 23/498

(52) U.S. Cl. 257/690; 257/738; 257/E23.069

(57) ABSTRACT

A die rearrangement package structure is provided, which includes an active surface of die with the pads; a first polymer material is covered on the active surface of die and the pads is to be exposed; the conductive posts is disposed among the first polymer material and is electrically connected to the pads; an encapsulated structure is covered the die and the first polymer material and the conductive posts is to be exposed; a second polymer material is covered on the first polymer material and the encapsulated structure to expose the conductive posts; the fan-out patterned metal traces are disposed on the second polymer material and one ends of each fan-out patterned metal traces is electrically connected to the conductive posts; and the conductive elements is electrically connected to another ends of the patterned metal traces.

### BACKGROUND OF THE INVENTION

1. Field of the Invention

The present invention is related to a semiconductor package method, and more particularly, is related to die rearrangement package method with a plurality of dies with different function and size.

2. Description of the Prior Art

The technology development in semiconductor is very fast, the microlize semiconductor dice is needed to have more functions therein. Thus, the microlize semiconductor dice needs to have more I/O pads within very tiny area, and the density of the pins is increased. Therefore, the conventional lead frame package technology is not good enough for high density pins, and a Ball Grid Array (BGA) package technology is developed. The BGA package technology is able to package the dice with high density pins and the solder ball is not easy to be damaged.

Because the 3C products, such as cell phone, portable digital assistant (PDA), or IPOD, are become more and more popular, the system die has to install in a tiny space. In order to solve this problem, a wafer level package (WLP) is invented. The WLP package can be done before the wafer is sawed into several dice. The U.S. Pat. No. 5,323,051 disclosed this kind of WLF package technology. However, when the number of the pads on the active surface of the dice is increased and the interval between the pads is too small, the signal in the dice will be overlapped or interrupted and the reliability of the package is decrease because of the small interval of the dice. Therefore, when the die is become smaller and smaller, the package technologies described above are not able to satisfy.

In order to solve the problem described above, U.S. Pat. No. 7,196,408 disclosed a package method that the wafer is done the testing and the sawing procedure in the semiconductor process and the good dice are put in another carrier board to do the package process. Therefore, those relocated dice are able to have a large interval and the pads on the dice can be arranged well. The fan-out technology is used and the problem of the small interval to cause the signal overlapped and interrupted can be solved.

However, in order to let the semiconductor die to have a smaller and thinner package structure, the wafer will do a thinning process, such as backside lapping, to thin the wafer in 2˜20 mil before sawing the wafer. Then, those die will put on another carrier board and form into an encapsulated structure by a molding method. Because the die is very thin, the package structure is also very thin. When the package structure is moved from the substrate, the stress from the package structure itself will let the package structure bend over and the difficulty of the sawing process is increased. Thus, the present invention provides the conductive posts which pre-formed on the pads of die and to expose the conductive posts by thinning process. Therefore, the drawback of mis-alignment for the ball mounting and warped of the encapsulated structure can be solved.

### SUMMARY OF THE INVENTION

According the problems described in prior art, the main object of the present invention is to provide a die rearrangement package structure and the forming method to relocate and package the plurality of dies. Thus, the present invention provides a conductive post which is formed on the die and the conductive posts are exposed by thinning process, so that the each die is able to accurately locate at the desired position during die rearrangement procedure.

It is another objective of the present invention is to provide a die rearrangement package structure and the method with a plurality of dies with different function and size on a substrate.

It is still an objective of the present invention is to provides a plurality of trenches which is formed on the surface of the encapsulated structure to prevent the warped of encapsulated structure after separating the encapsulated structure from the substrate.

It is yet an object of the present invention is to provide a die rearrangement package method and the method is able to cut the 12 inches wafer to be a lot of dies and the dies are relocated on 8 inches wafer substrate. Therefore, the 8 inches wafer package equipment can use to do the 12 inches package work without rebuilding new 12 inches package equipment.

It is another object of the present invention is to provide a die rearrangement package method to package the known good die to save the package materials and reduce the package cost.

According to above objectives, the present invention provides a die rearrangement package structure, which includes: a die having an active surface with a plurality of pads and a reverse surface; a first polymer material which is covered on the active surface of the die to expose the plurality of pads; a plurality of conductive posts which is disposed among the first polymer material and is electrically connected to the plurality of exposed pads; an encapsulated structure which is covered around the five surfaces of the die to expose the first polymer material and the plurality of conductive posts; a second polymer material which is covered on the first polymer material and the encapsulated structure to expose the plurality of conductive posts; a plurality of fan-out patterned metal traces which is disposed on the second polymer material and each plurality of fan-out pattered metal traces is electrically connected to the plurality of conductive posts; a protective layer which is covered on the second polymer material and the plurality of fan-out patterned metal traces to expose a top surface on one ends of the plurality of fan-out patterned metal traces; and a plurality of conductive elements which is electrically connected to another ends of the plurality of fan-out patterned metal traces.

In addition, the present invention provides a module multi-die package structure, which includes: a plurality of dies, each plurality of dies having an active surface with a plurality of pads; a first polymer material which is covered on the active surface of each plurality of dies to expose the plurality of pads; a plurality of conductive posts, which is disposed among the first polymer material and is electrically connected to the plurality of exposed pads; an encapsulated structure, which is covered around the five surfaces of each plurality of dies to expose the first polymer material and the plurality of conductive posts; a second polymer material which is covered on the first polymer material and the encapsulated structure to expose the plurality of conductive posts; a plurality of patterned metal traces which is disposed on the second polymer material and the portion of one ends of the plurality of patterned metal traces is electrically connected to the plurality of conductive posts, and another ends of the plurality of patterned metal traces is electrically connected to the plurality of conductive posts; a patterned protective layer which is covered on the second polymer material and the plurality of patterned metal traces to expose another ends of the plurality of exposed patterned metal traces; and a plurality of conductive elements, which is electrically connected to another ends of the plurality of patterned metal traces.

Furthermore, the present invention provides a multi-die package method, which includes providing a wafer having a plurality of dies with a plurality of pads thereon and a reverse surface; forming a first polymer material on the wafer to cover the plurality of pads on the active surface of the pluralit of dies; forming a plurality of first openings in the first polymer material to expose the plurality of pads; forming a plurality of condutive posts within the plurality of the first openings, and one ends of the plurality of conductive posts which is electrically connected to the plurality of pads; sawing the wafer to form a plurality of dies; providing a substrate with an adhesive layer thereon; pick and placing the plurality of dies on the adhesive layer by flip-chip technology, the first polymer material which is formed on each plurality of dies and the plurality of conductive posts is fixedly connected on the adhesive layer of the substrate; forming a second polymer material among each plurality of dies and the adhesive layer on the substrate to form an encapsualted structure; separating the substrate and the encapsualted structure to expose the first polymer material, the second polymer material, and the plurality of conductive posts; forming a third polymer material on the first polymer material and the second polymer material; forming a plurality of second openings in the rhird polymer material to expose the plurality of conductive posts; forming a plurality of patterned metal traces on the third polymer material, and one ends of the plurality of patterned metal traces is electrically connected to the plurality of conductive posts; forming a patterned protective layer to cover the plurality of patterned metal traces to expose another ends of the plurality of patterned metal traces; forming a plurality of conductive elements to electrically connect to another ends of each plurality of exposed patterned metal traces; and cutting the encapsualted structure to form a multi-die package structure.

In addition, the present invention provides a module multi-die package method, which includes providing a wafer having a plurality of dies with a plurality of pads thereon and a reverse surface; forming a first polymer material on the wafer to cover the plurality of pads on the active surface of the pluralit of dies; forming a plurality of first openings in the first polymer material to expose the plurality of pads; forming a plurality of condutive posts within the plurality of the first openings, and one ends of the plurality of conductive posts which is electrically connected to the plurality of pads; sawing the wafer to form a plurality of dies; providing a substrate with an adhesive layer thereon; pick and placing the plurality of dies on the adhesive layer by flip-chip technology, the first polymer material which is formed on each plurality of dies and the plurality of conductive posts is fixedly connected on the adhesive layer of the substrate; forming a second polymer material among each plurality of dies and the adhesive layer on the substrate to form an encapsualted structure; separating the substrate and the encapsualted structure to expose the first polymer material, the second polymer material, and the plurality of conductive posts; forming a third polymer material on the first polymer material and the second polymer material; forming a plurality of second openings in the rhird polymer material to expose the plurality of conductive posts; forming a plurality of patterned metal traces on the third polymer material, and one ends of the plurality of patterned metal traces is electrically connected to the plurality of conductive posts; forming a patterned protective layer to cover the plurality of patterned metal traces to expose another ends of the plurality of patterned metal traces; forming a plurality of conductive elements to electrically connect to another ends of each plurality of exposed patterned metal traces; and cutting the encapsualted structure to form a module multi-die package structure.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A and FIG. 1B are views showing that the vertical views and the cross-sectional view of the wafer in accordance with the present invention;

FIG. 2A and FIG. 2B are views showing that the conductive post disposed on the die in accordance with the present invention;

FIG. 3A to FIG. 3F are views showing that the forming process of package structure in accordance with the present invention;

FIG. 4A and FIG. 4B are views showing that the vertical view and the cross-sectional view of the package structure in accordance with the present invention;

FIG. 5 is a view showing that the multi-die package structure in accordance with the present invention;

FIG. 6A and FIG. 6B are views showing that the multi-die package structure in accordance with the another embodiment of the present invention; and

FIG. 7 is a view showing that the module package structure with multi-die in accordance with the present invention.

### DESCRIPTION OF THE PREFERRED EMBODIMENT

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components.

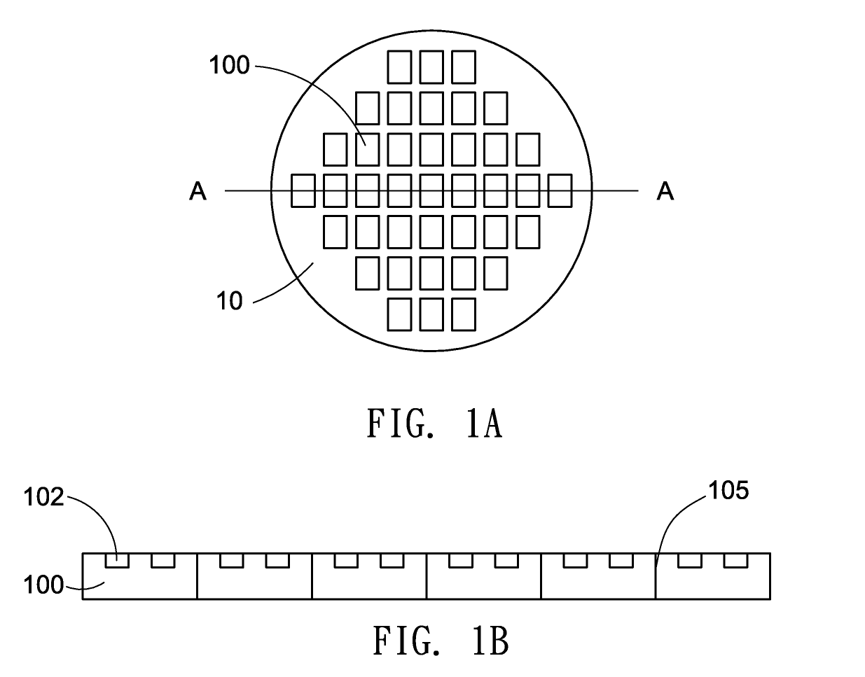

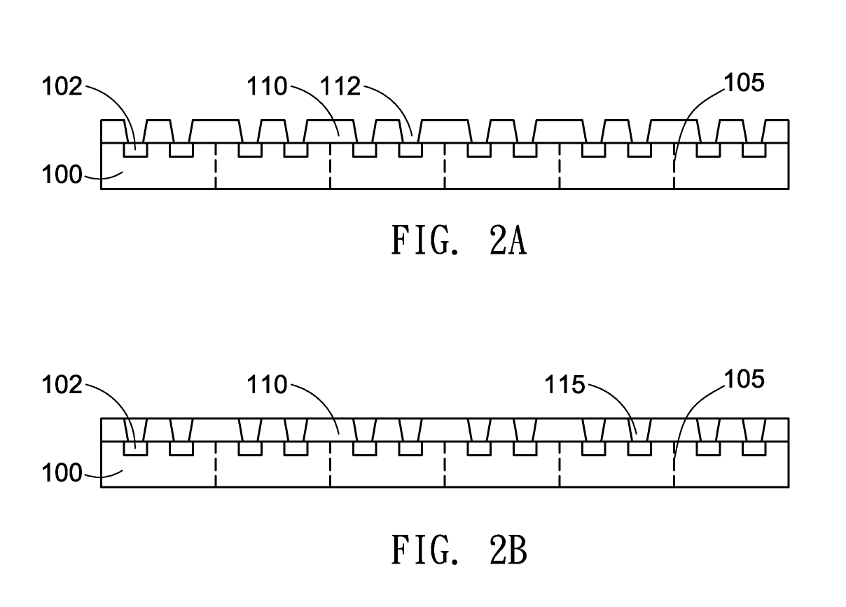

In the present semiconductor package method, the wafer done with the front end process will do a thinning process as shown in FIG. 1A, such as thinning the wafer 10 to be 2˜20 mil thick as shown in FIG. 1B. In FIG. 1B, the dotted line 105 shows the location for each die, and is used as the sawing lines for follow-up process. Next, a polymer material 110 is formed on the active surface of the wafer 10 to cover the plurality of pads 102 on the active surface of the die, in which the polymer material 110 such as polyimide. Then, the polymer material 110 is removed to form a plurality of openings 112 and to expose each pad 102 of die 10 by using semiconductor manufacturing process as shown in FIG. 2A. Next, a metal material is filled to the openings 112 to form a conductive post 115 by using the PVD (physical vapor deposition) process or CVD (chemical vapor deposition) process. The conductive post 115 electrically connected to the each pad 102 on the active surface of die 10 as shown in FIG. 1D. In this embodiment, the thickness of the polymer material 110 can be 0.5 mil˜10 mil, and the thickness of the conductive post 115 can be 0.5 mil˜3 mil. The material of conductive post 115 can be the material with hardness such as Cu or Cu alloy.

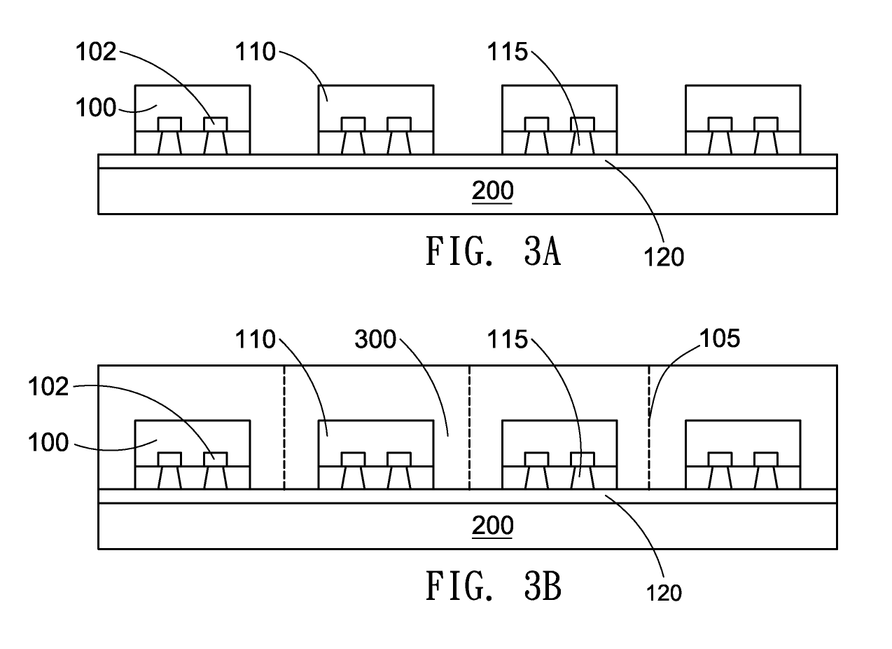

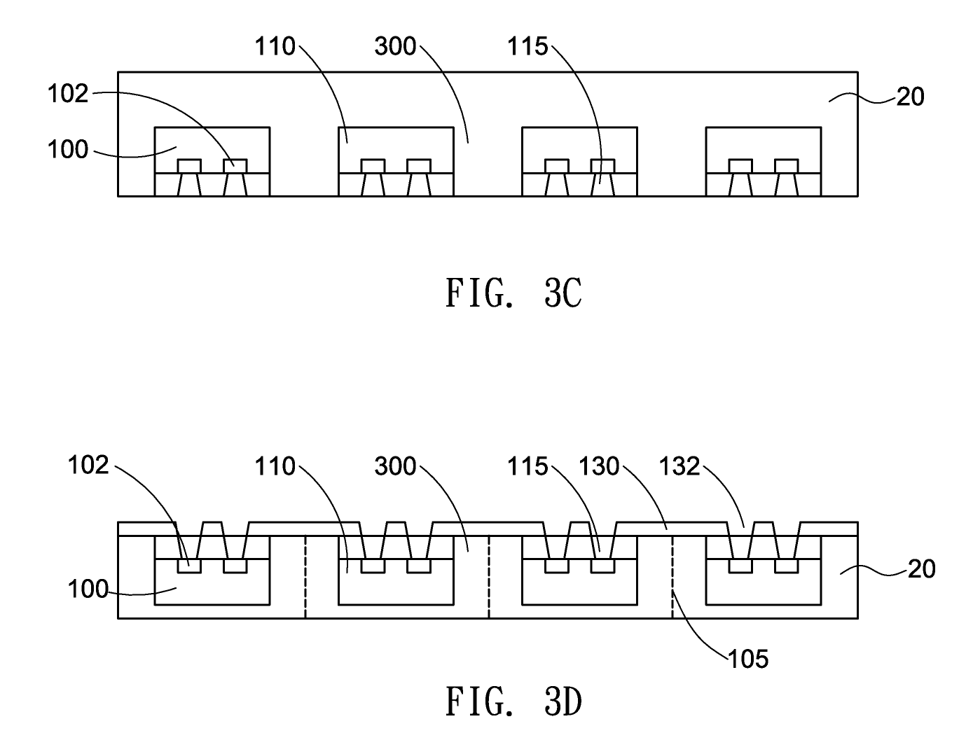

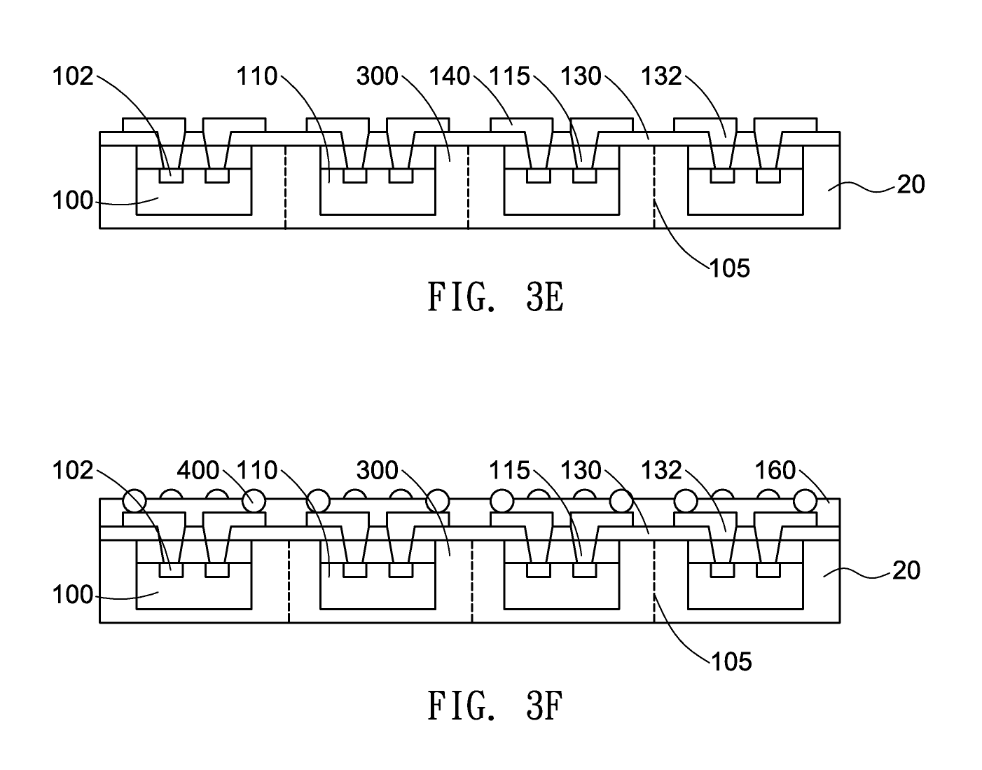

After, a sawing process is performed to cut the wafer 10 along the dotted lines 105 to form a plurality of dies 100. The pick and place apparatus (not shown) is able to pick the good die 100 to fixed on the adhesive layer 120 on the another substrate 200 such that the conductive post 115 on the die 100 is fixedly connected on the adhesive layer 120 as shown in FIG. 3A. In this embodiment, the material of adhesive layer 120 is an elastic adhesive material, such as silicon rubber, silicon resin, elastic PU, porous PU, acrylic rubber, or die cutting glue. It is obviously, the distance among the dies on the substrate 200 is larger than the distance among the wafer 10. Moreover, the dies saw from the 12-inches wafer may be rearranged on an 8-inches wafer and implemented by conventional package equipments for 8-inches wafers without setting new equipments for 12-inches wafers. It is noted that the present invention is not limited to 8-inches wafers. Any substrate which may support dices and be in any shape, such as glass, quartz, ceramic, PCB or metal foil, is utilized for the substrate 200 in the present invention.

Next, referring to FIG. 3B, the die 100 with a plurality of conductive posts 115 is first disposed on the adhesive layer 120 on the substrate 200 accurately. Then, a polymer material 300 is formed on the reverse side (not shown) of each die 100 and the substrate 200, such that the polymer material 300 is filled among the die 100 and covered around the five surfaces of die 100 except for the active surface of die 100 to form an encapsulated structure 20. In this embodiment, the material of polymer material 300 can be silicon rubber, epoxy, acrylic, and BCB. Next a baking process is selected to solid the polymer material 300. At this time, the cutting knife is used to form a plurality of sawing lines (not shown) on the surface of the polymer material 300, in which the depth of each sawing line is about 0.5 mil˜1 mil, and the width of is about 5 um to 25 um. In one embodiment, the sawing line can select on the sawing line 195 to solve the warped of the encapsulated structure 20.

Please refer to FIG. 3C, a separating process to separate the substrate 200 from the polymer material 300, in which the steps include: the substrate 200 and polymer material 300 are put in the tank with de-ion water to separate the adhesive layer 120 on the substrate 200 from the polymer material 300 to form an encapsulated structure 20. Meanwhile, the plurality of conductive posts 115 on the active surface of each die 100 is exposed. Next, a polymer material 130 is formed on the active surface of each die 100, and the portion of the polymer material 130 on the each plurality of conductive posts 115 is removed to expose each conductive post 115 as shown in FIG. 3D. After, a plurality of patterned metal traces 140 is formed by fan-out technology, and one ends of each patterned metal traces 140 is electrically connected to the conductive post 115, another ends of the patterned metal traces is formed as free end. It is obviously that the free ends of the patterned metal traces would not form on the pads 102 of the die 100 as shown in FIG. 3E. In addition, the material of metal trace 140 can be Cu, Au, or Cu alloy; meanwhile, the metal trace 140 can be formed by UBM layer, and material of UBM layer can be Ti/Cu or TiW/Cu.

Then, the conductive elements are disposed after the plurality of patterned metal traces 140 is formed on the encapsulated structure 20. As shown in FIG. 3F, a patterned protective layer 160 is formed on the surface of the patterned metal traces 140 on the encapsulated structure 20 to expose the plurality of free ends of the patterned metal traces 140. the forming steps of the patterned metal traces includes: a patterned photoresist layer is formed on the protective layer 60 by a semiconductor manufacturing process such as developing; next, the portion of plurality of patterned metal traces 140 is removed to expose the free ends of the patterned metal traces 140. Then, a plurality of conductive elements 400 is formed on the free ends of the patterned metal traces 140, in which the conductive elements 400 can be solder ball or metal bump as shown in FIG. 3F. It is obviously, the conductive elements can arrange on the free ends of the patterned metal traces 140 according to the requirement, such as BGA (ball grid array) arrangement.

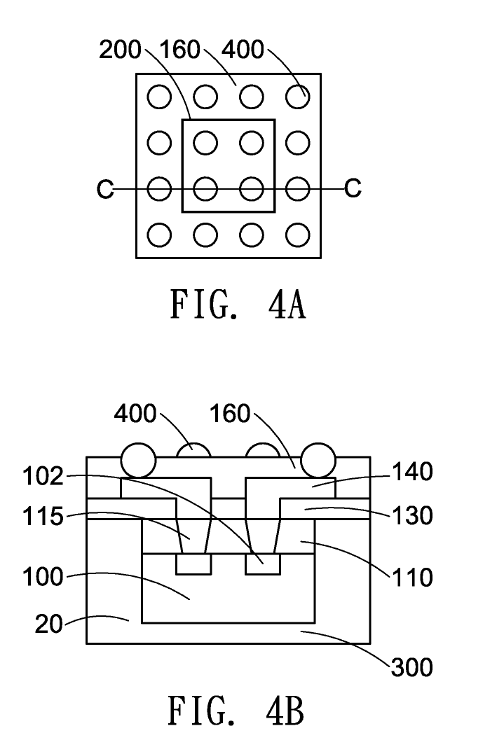

Finally, a die sawing process is performed to the encapsulated structure 20 along the sawing line 105 to obtain a plurality of packaged die or package module as shown in FIG. 4A and FIG. 4B. It is obviously, FIG. 4B is a cross-sectional view along C-C line of the FIG. 4A.

In above embodiments, the formation of the polymer material 300 covered each die 100 is stamping process or molding process. In addition, due to the plurality of conductive posts 115 on the active surface of each die are exposed after separating the substrate and encapsulated structure, the connecting alignment of the metal trace can be solved. Therefore, a plurality of good dies with or without identical function can be electrically connected to each other by the patterned metal traces 400 to form a package module with a plurality of dies 100. For example, the four dies such as DRAM (dynamic random access memory) with 256 MB respectively is electrically connected to each other in series or in parallel to form a DRAM module with 1 GB capacity. Alternatively, a plurality of LEDs (light emitting diodes) is electrically connected in series connection to form a plane light source or in parallel connection for column light source. In addition, the plurality of dies with different function is also electrically connected to each other to package a system packaged module.

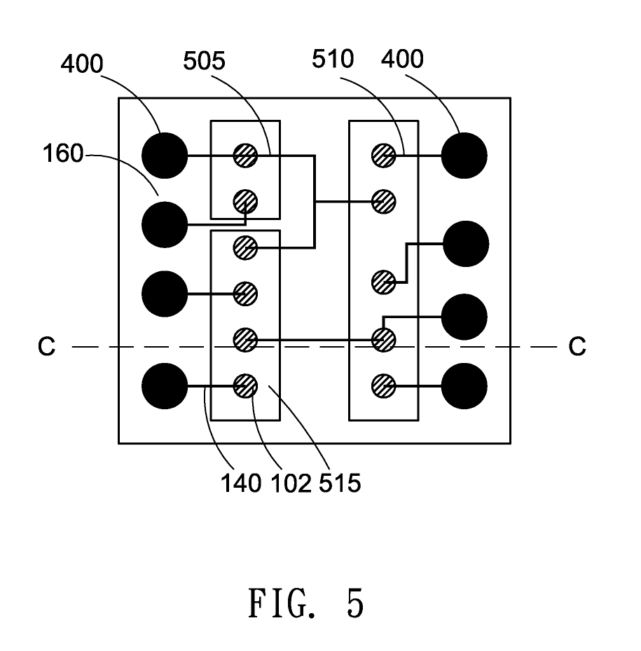

Next, FIG. 5 is a vertical view showing that another embodiment of the present invention of the SIP (System-In-Chip). The plurality of dies with different function such as microprocessor means (die 505), memory controller means (die 510) and the memory means (die 515) is placed on another substrate 200. Next, a plurality of conductive posts 115 is formed on each pads of each die 505, 510, and 515. Then, referring to FIG. 3A to FIG. 3F again, an encapsulated structure 20 is formed to cover the plurality of dies with different function. Next, each conductive post 115 on the pads of each die 505, 510, 515 is exposed at same plane after separating the substrate 200 and the encapsulated structure 20. Thus, the alignment can be solved effective.

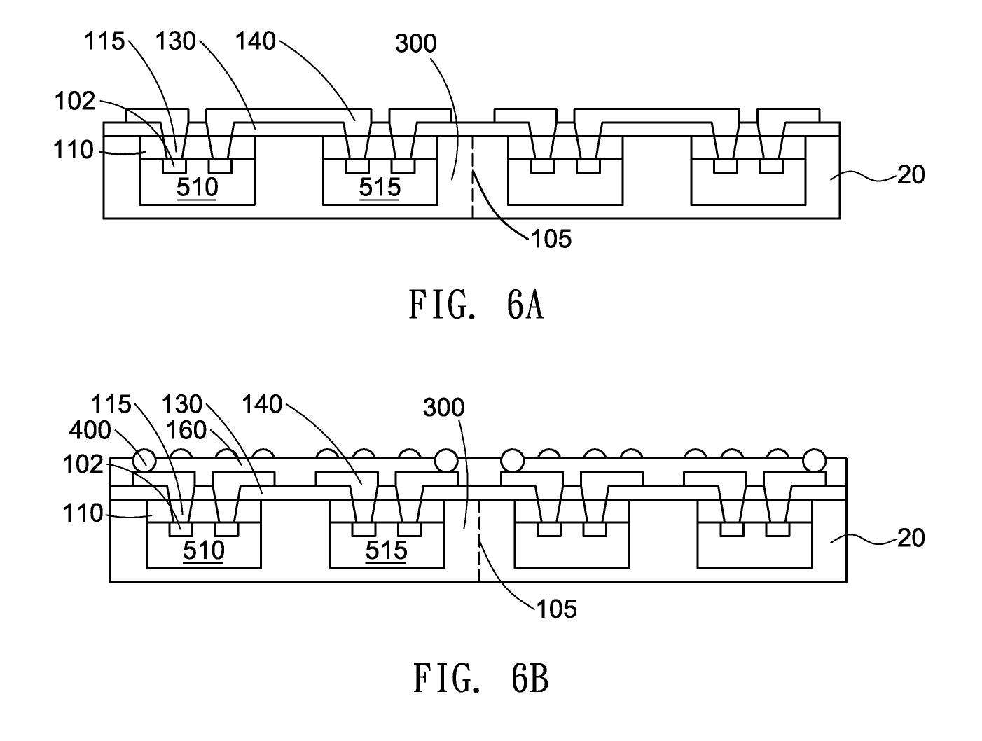

After, a polymer material 130 is formed on the encapsulated structure 20 to expose each conductive post 115 on the pads of each die by a semiconductor process such as developing process. Then, an electroplating process is used to form a metal layer (not shown) on the polymer material 300 and is electrically connected to each conductive post 115. Next, a patterned photoresist layer (not shown) is formed on the metal layer by another semiconductor process such as coating, developing or etching. Then, a portion of the metal layer is removed to form a patterned metal traces 140 on the polymer material 300 to electrically connect to each conductive post 115 on each pads of each die. The connection can be in series or in parallel as shown in FIG. 6A. It is noted that the connection between the plurality of dies can utilize the required connection, and it would not limited in this embodiment.

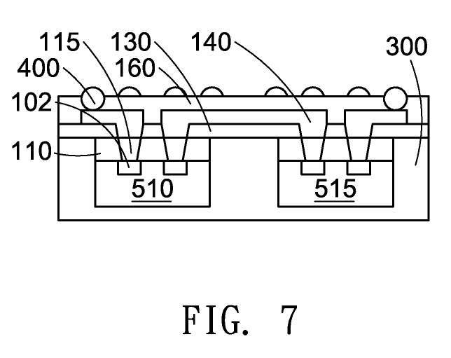

Next, the plurality of conductive elements 400 is used as the connecting elements to electrically connect to outer elements (not shown) after the patterned metal traces is electrically connected to the plurality of dies, in which the manufacturing process of the conductive elements is same as the above FIG. 3A through FIG. 3F, therefore, the process is not describe herein. It is obviously, the conductive element 400 can be solder ball or metal bump, and the conductive elements 400 can arrange on the free ends of the patterned metal traces 140 according to the requirement, such as BGA arrangement as shown in FIG. 6B. Finally, a die sawing process is performed to the encapsulated structure 20 along the sawing line 105 to obtain a plurality of module packaged die as shown in FIG. 7.

It is obviously, the plurality of dies with identical function, such as LED, in which plurality of dies (LED) can electrically connect each other by using the patterned metal traces 140 in series or in parallel connection to form a module package structure. In this embodiment, the material of metal trace 140 can be Cu, Au, or Cu alloy; meanwhile, the metal trace 140 can be formed by UBM layer, and material of UBM layer can be Ti/Cu or TiW/Cu.

When the plurality of dies is LED, the p electrode of each LED is electrically connected to adjacent the P electrode of another LED, and the N electrode of each LED is electrically connected to the adjacent N electrode of another LED. In addition, the conductive post 115 on the N electrode and P electrode of each LED is electrically connected to each other by the patterned metal traces 140. Similarly, the connecting type is not limited in this embodiment, for example, the plurality of LEDs is electrically connected to each other in series to form a plane light source, or in parallel connection for a column light source. Meanwhile, the color of the LEDs is also not limited, such as red LEDs, green LEDs, or blue LEDs, or white LEDs. Thereafter, as shown in FIG. 3E to FIG. 3F again, the plurality of conductive elements 400 is disposed on the exposed free ends of the patterned metal traces 140.

What is claimed is:

1. A die rearrangement package structure, comprising:
a die having an active surface with a plurality of pads and a reverse surface;
a first polymer material, which is covered on said active surface of said die to expose said plurality of pads;
a plurality of conductive posts, which is disposed among said first polymer material and is electrically connected to said plurality of exposed pads;
an encapsulated structure, which is covered around the five surfaces of said die to expose said first polymer material and said plurality of conductive posts;
a second polymer material, which is covered on said first polymer material and said encapsulated structure to expose said plurality of conductive posts;
a plurality of fan-out patterned metal traces, which is disposed on said second polymer material and each said plurality of fan-out patterned metal traces is electrically connected to said plurality of conductive posts;
a protective layer, which is covered on said second polymer material and said plurality of fan-out patterned metal traces to expose a top surface on one ends of said plurality of fan-out patterned metal traces; and
a plurality of conductive elements, which is electrically connected to said another ends of said plurality of fan-out patterned metal traces.

2. The package structure according to claim 1, wherein the material of said conductive posts is Cu or Cu alloy.

3. The package structure according to claim 1, wherein the material of said package body is polymer material.

4. The package structure according to claim 3, wherein the material of said polymer material is selected from the group consisted of silicon rubber, epoxy, acrylic, and BCB.

5. The package structure according to claim 1, wherein the material of said plurality of fan-out patterned metal traces is UBM material.

6. The package structure according to claim 1, wherein the material of said conductive element is solder ball.

7. The package structure according to claim 1, wherein the material of said conductive element is metal bump.

8. The package structure according to claim 1, wherein the material of said first polymer material and said second polymer material is polyimide.

9. A module multi-chip package structure, comprising:
a plurality of dies, each said plurality of dies having an active surface with a plurality of pads;
a first polymer material, which is covered on said active surface of each said plurality of dies to expose said plurality of pads;
a plurality of conductive posts, which is disposed among said first polymer material and is electrically connected to said plurality of exposed pads;
an encapsulated structure, which is covered around the five surfaces of each said plurality of dies to expose said first polymer material and said plurality of conductive posts;
a second polymer material, which is covered on said first polymer material and said encapsulated structure to expose said plurality of conductive posts;
a plurality of patterned metal traces, which is disposed on said second polymer material and the portion of one ends of said plurality of patterned metal traces is electrically connected to said plurality of conductive posts, and another ends of said plurality of patterned metal traces is electrically connected to said plurality of conductive posts;
a patterned protective layer, which is covered on said second polymer material and said plurality of patterned metal traces to expose another ends of said plurality of exposed patterned metal traces; and
a plurality of conductive elements, which is electrically connected to another ends of said plurality of patterned metal traces.

10. The package structure according to claim 9, wherein the material of said conductive posts is Cu or Cu alloy.

11. The package structure according to claim 9, wherein said plurality of dies with identical function and size.

12. The package structure according to claim 9, wherein said plurality of dies is memory means.

13. The package structure according to claim 9, wherein said plurality of dies is LED (light emitting diode) die.

14. The package structure according to claim 9, wherein said plurality of dies with different functions and sizes.

15. The package structure according to claim 9, wherein said plurality of dies consisted of microprocessor means, memory means, and memory controlling means.

16. The package structure according to claim 9, wherein the material of said encapsulated structure is polymer material.

17. The package structure according to claim 16, wherein the material of polymer material is selected from the group consisted of silicon rubber, epoxy, acrylic, and BCB.

18. The package structure according to claim 9, wherein the material of said patterned metal traces is UBM layer.

19. The package structure according to claim 9, wherein the material of said conductive element is solder ball.

20. The package structure according to claim 9, wherein the material of said conductive element is metal bump.
